(19) United States
(12) Patent Application Publication
(10) Pub. No.: US 2007/0074741 A1
(43) Pub. Date: Apr. 5, 2007

(54) Method for dry cleaning nickel deposits from a processing system

(75) Inventors: Gordon Bease, Austin, TX (US); Hongyun Cottle, Austin, TX (US)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/239,295

(22) Filed: Sep. 30, 2005

(51) Int. Cl. B08B 7/04; B08B 7/00; B08B 9/00; H01L 21/306

(52) U.S. Cl. 134/18; 134/22.1; 134/19; 156/345.24

(57) ABSTRACT

A method for dry cleaning a process chamber including a nickel deposit. The method includes exposing a system component in the process chamber to a process gas with a carbonyl gas, reacting the nickel deposit on the system component with the carbonyl gas in a dry cleaning process to form a gaseous nickel carbonyl product, and exhausting the gaseous nickel carbonyl product from the process chamber. A mass signal of the nickel carbonyl product can be used to monitor and control the dry cleaning process.

### FIELD OF THE INVENTION

The present invention relates to chamber cleaning, and more particularly, to a dry cleaning process for removing nickel deposits from system components of a processing system.

### DISCUSSION OF THE RELATED ART

Many device manufacturing processes are performed in processing systems such as plasma etching systems, plasma deposition systems, thermal processing systems, chemical vapor deposition systems, atomic layer deposition systems, etc. Processing of a substrate can lead to formation of material deposits (residues) on system components that are exposed to the process environment in a process chamber of the processing system. The material deposits can be detrimental to device manufacturing and can require periodic wet or dry cleaning of the system components to remove the material deposits.

System components are commonly replaced or cleaned after material deposits present impending or realized particle problems, between incompatible processes to be run in sequence, and/or after detrimental processing conditions or poor processing results are observed. As device geometries have shrunk and tolerances on particle sizes and particle levels in process chambers and on processed substrates have become more stringent, the frequency of chamber cleans has increased, thereby lowering the throughput of processing systems and increasing the cost of ownership.

Nickel (Ni) metal and Ni-containing materials are widely used in manufacturing of integrated circuits. The manufacturing processes can include physical vapor deposition (PVD) of Ni metal onto a substrate in a low pressure processing system and can include plasma etching of patterned features on the substrate. During the manufacturing processes, unwanted Ni and Ni-containing materials may become deposited onto surfaces of system components. For example, plasma etching of a NiSi layer can redeposit NiSi or other Ni-containing materials onto the system components exposed to the processing environment.

Commonly, Ni and Ni-containing materials are removed from system components by physical cleaning (e.g., by hand) or by removing and replacing the contaminated system component(s) in the processing system (using a “process kit”), or by a combination of these methods. However, as these methods are generally slow, time-consuming, and expensive to perform, alternative cleaning methods are desirable for efficiently removing Ni and Ni-containing materials from system components.

### SUMMARY OF THE INVENTION

Various embodiments of the invention provide methods for dry cleaning nickel deposits from a system component of a processing system. The nickel deposits dry cleaned by the present invention can include nickel metal, nickel silicide, or nickel oxide. Accordingly, the dry cleaning methods of the present invention can dry clean system components such as for example a chamber wall, a substrate holder, an electrode, a shield, a ring, a baffle, or a liner.

According to one embodiment of the present invention, the method exposes a system component in the process chamber to a process gas including a carbonyl gas, reacts the nickel deposit on the system component with the carbonyl gas in a dry cleaning process to form a gaseous nickel carbonyl product, and exhausts the gaseous nickel carbonyl product from the process chamber. The process gas can include CO₂, CO, or a combination thereof, and may further include an inert gas.

According to another embodiment of the present invention, the method further monitors and controls the dry cleaning process by monitoring a mass signal from the gaseous nickel carbonyl product or fragments thereof, compares the mass signal to a threshold signal value, and terminates the dry cleaning process upon the mass signal reaching the threshold signal value.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 shows a simplified block diagram of a processing system according to an embodiment of the present invention;

FIG. 2 is a process flowchart, according to an embodiment of the present invention, for dry cleaning of nickel deposits from a processing system;

FIG. 3 is a process flowchart, according to an embodiment of the present invention, for monitoring and controlling dry cleaning of nickel deposits from a processing system; and

FIGS. 4A and 4B are schematics depicting the monitoring, according to various embodiments of the present invention, of dry cleaned nickel deposits from a processing system.

### DETAILED DESCRIPTION OF EMBODIMENTS OF THE INVENTION

In the following description, in order to facilitate a thorough understanding of the invention and for purposes of explanation and not limitation, specific details are set forth, such as a particular structure of a semiconductor device and geometry of a batch processing system and descriptions of various components. However, it should be understood that the invention may be practiced in other embodiments that depart from these specific details. Various embodiments of the present invention provide a method for dry cleaning of nickel deposits from a processing system.

The nickel deposits referred to in the present invention may be deposits on surfaces of system components exposed to a process environment during the processing of a substrate. For example, nickel deposits can include elemental Ni from a Ni physical vapor deposition (PVD) process. In another example, in the process of the plasma etching of a NiSi layer on a substrate, NiSi or other Ni-containing materials can redeposit onto the system components exposed to the processing environment. In these and other examples, the nickel deposits may contain nickel oxide.

Various embodiments of the present invention can replace or compliment physical cleaning of nickel deposits from system components of a processing system, thereby improving system throughput and reducing the operational cost of the system. In practice, multiple film materials can be processed in the same processing system, and cleaning of the processing system is required to maintain practical usage of the processing system. System components can include consumable or replaceable components such as shield and liners as well as process chamber walls and other non-consumable components of the processing system.

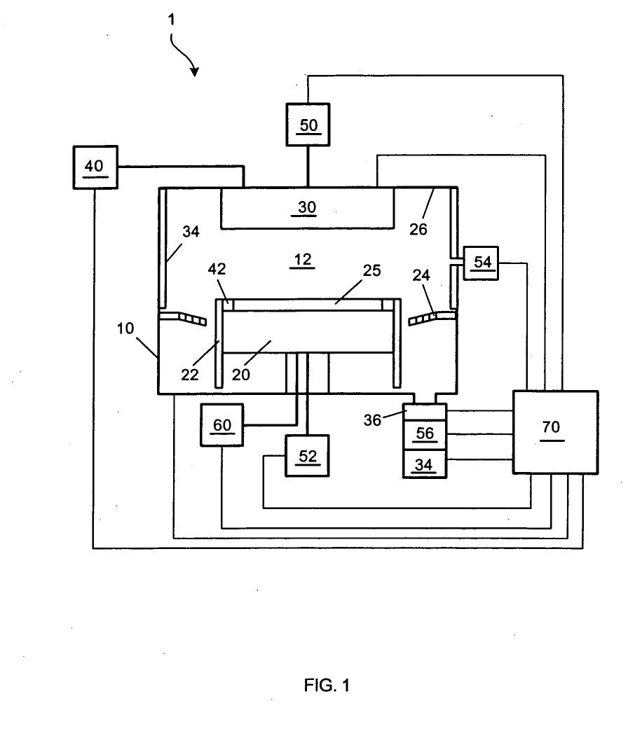

In general, various embodiments of the present invention can be utilized for dry cleaning nickel deposits from various types of processing systems utilized for processing nickel-containing material including thermal processing systems and plasma processing systems. The various embodiments of the present invention are not limited to only those processing systems as other processing systems may be treated without departing from the scope of the present invention. It is to be understood that the processing system 1 depicted in FIG. 1 is shown for exemplary purposes only, as many variations of the specific hardware can be used to practice embodiments of the invention.

FIG. 1 shows a simplified block diagram of a processing system according to an embodiment of the present invention. The processing system 1 can be configured to process various substrates (i.e., 200 mm substrates, 300 mm substrates, or larger), for example for depositing a layer onto the substrate 25 or dry etching the substrate 25. The plasma processing system 1 depicted in FIG. 1 includes a plasma generation system configured to generate a plasma during at least a portion of the process performed in the process chamber 10. The plasma generation system can include a power source 50 coupled to the process chamber 10. The power source 50 may be a variable power source and may include a radio frequency (RF) generator and an impedance match network, and may further include an electrode through which RF power can be coupled to the plasma in process chamber 10. The electrode can be formed in the upper assembly 30, and the electrode can be configured to oppose the substrate holder 20. The impedance match network can be configured to optimize the transfer of RF power from the RF generator to the plasma by matching the output impedance of the match network with the input impedance of the process chamber, including the electrode and plasma. For instance, the impedance match network serves to improve the transfer of RF power to plasma in plasma process chamber 10 by reducing the reflected power. Matching network topologies (e.g. L-type, π-type, T-type, etc.) and automatic control methods can be used.

Alternatively, the power source 50 may include a radio frequency (RF) generator and an impedance match network, and may further include an antenna, such as an inductive coil, through which RF power can be coupled to a plasma in process chamber 10. The antenna can, for example, include a helical or solenoidal coil, such as in an inductively coupled plasma source or helicon source, or the antenna can, for example, include a flat coil as in a transformer coupled plasma source.

Alternatively, the power source 50 may include a microwave frequency generator, and may further include a microwave antenna and microwave window through which microwave power can be coupled to plasma in the process chamber 10.

Optionally, the processing system 1 can include a substrate bias generation system configured to generate or assist in generating a plasma during at least a portion of the process performed in the process chamber 10. The substrate bias system can include a substrate power source 52 coupled to the process chamber 10, and configured to couple power to substrate 25. The substrate power source 52 may include a radio frequency (RF) generator and an impedance match network, and may further include an electrode through which RF power can be coupled to substrate 25. The electrode can be formed in substrate holder 20. For instance, the substrate holder 20 can be electrically biased at a RF voltage via the transmission of RF power from a RF generator (not shown) through an impedance match network (not shown) to substrate holder 20. A typical frequency for the RF bias can range from a vicinity of 0.1 MHz to a vicinity of 100 MHz. Alternately, RF power can be applied to the substrate holder electrode at multiple frequencies.

Although the plasma generation system and the optional substrate bias system are illustrated in FIG. 1 as separate entities, these systems may indeed include one or more power sources coupled to substrate holder 20.

Still referring to FIG. 1, the processing system 1 can include a substrate temperature control system 60 coupled to the substrate holder 20 and configured to elevate and control the temperature of substrate 25. Substrate temperature control system 60 can include temperature control elements, such as a cooling system including a re-circulating coolant flow that receives heat from substrate holder 20 and transfers heat to a heat exchanger system (not shown). When heating, substrate temperature control system 60 by way of the temperature control elements can transfer heat from the heat exchanger system to the substrate holder 20. Additionally, the temperature control elements can include heating/cooling elements, such as resistive heating elements, or thermoelectric heaters/coolers, which can be included in the substrate holder 20, as well along the chamber wall 26 of the process chamber 10 or on any other system component within the deposition system 1.

In order to improve the thermal transfer between substrate 25 and substrate holder 20, the substrate holder 20 can include a mechanical clamping system, or an electrical clamping system, such as an electrostatic clamping system, to affix substrate 25 to an upper surface of substrate holder 20. Furthermore, substrate holder 20 can further include a substrate backside gas delivery system configured to introduce gas to the back-side of substrate 25 in order to improve the gas-gap thermal conductance between the substrate 25 and the substrate holder 20. Such a system can be utilized when temperature control of the substrate is required at elevated or reduced temperatures. For example, the substrate backside gas system can include a two-zone gas distribution system such that the helium gas gap pressure can be independently varied between the center and the edge of substrate 25. In one example, the temperature of the substrate 25 can be rapidly raised or lowered by controlling the thermal conductance between the substrate 25 and substrate holder 20 for example by de-energizing/energizing the electrical clamping system and/or removing/supplying the back-side gas. The rapid raising or lowering of the substrate temperature can be performed without significantly varying the temperature of the substrate holder 20.

Furthermore, the process chamber 10 can be further coupled to a pressure control system that includes a vacuum pumping system 34 and a valve 36 configured to controllably evacuate the process chamber 10 to a pressure suitable for the processes to be performed in the process chamber 10.

The vacuum pumping system 34 can include a turbo-molecular vacuum pump (TMP) or a cryogenic pump capable of a pumping speed up to about 5000 liters per second (and greater) and can include valve 36 such as for example a gate valve for throttling the gas flow from the process chamber 10 to the vacuum pumping system 34, thereby controlling the process chamber pressure. Moreover, a device for monitoring chamber pressure (not shown) can be coupled to the processing chamber 10. The pressure measuring device can be for example a Type 628B Baratron absolute capacitance manometer commercially available from MKS Instruments, Inc. (Andover, Mass.).

The gas injection assembly 40 can introduce a process gas to the process chamber 10. The gas injection system 40 can include a showerhead such that the process gas is supplied from a gas delivery system (not shown) to a process space 12 above the substrate 25 through a gas injection plenum (not shown), a series of baffle plates (not shown), and/or a multi-orifice showerhead gas injection plate (not shown). According to one embodiment of the invention, the gas injection assembly 40 can further include a remote microwave plasma source or an ultra-violet (UV) plasma source for exciting and introducing the excited process gas into the process space 12.

The processing system 1 can further include mass sensors 54 and 56 for monitoring the gaseous environment in the process chamber 10 and for monitoring the gases exhausted from the process chamber 10, respectively. The mass sensors 54 and 56 may be mass spectrometers for example quadrupole mass spectrometers (QMS). Mass spectrometers are permit detection, identification, and analysis of the components of a gaseous environment, and can detect trace amounts of gaseous substances. During monitoring, the gaseous material is ionized through various techniques such as for example thermionic or cold cathode electron emission, and the ions are collected in a mass filter of the spectrometer. The ion signals are then translated into a spectrum of mass signals that are used to identify the relative amounts of atoms or molecules present in the gaseous environment. Due to the relatively high pressure at the process monitoring point of a typical process, the gas sampling may include a pressure reduction system. The pressure reduction is carried out using a length of capillary tube or a throttle valve, and the mass spectrometer itself can be pumped continuously.

The process chamber 10 can further include various shields and liners in the process space 12 for protecting the process chamber 10 from the processing environment. For example, depicted in FIG. 1 are a chamber liner 34 and a baffle plate 24 about a periphery of the substrate holder 20, a focus ring 42 that encircles the substrate 25, and a shield ring 22 that encircles the substrate holder 20. The focus ring 42 affects the substrate etch rate, etch selectivity, and etch uniformity on the periphery of the substrate 25. Erosion or deposition of the order of few tenths of a mm in the thickness of the focus ring 42 can require replacement or cleaning of the focus ring 42.

Still referring to FIG. 1, controller 70 can include a microprocessor, memory, and a digital I/O port capable of generating control voltages sufficient to communicate and activate inputs to the processing system 1 as well as monitor outputs from the processing system 1. Moreover, the controller 70 may be coupled to and may exchange information with the process chamber 10, gas delivery system 40, substrate temperature controller 60, power source 52, vacuum pumping system 34, valve 36, mass sensors 54 and 56, upper assembly 30, and power sources 50 and 52. For example, a program stored in the memory may be utilized to activate the inputs to the aforementioned components of the processing system 1 according to a process recipe in order to perform an etching process, a deposition process, or one of the dry cleaning process of the present invention. One example of the controller 70 is a DELL PRECISION WORKSTATION 610™, available from Dell Corporation, Austin, Tex.

However, the controller 70 may be implemented as a general purpose computer system that performs a portion or all of the microprocessor based processing steps of the present invention in response to a processor executing one or more sequences of one or more instructions contained in a memory. Such instructions may be read into the controller memory from another computer readable medium, such as a hard disk or a removable media drive. One or more processors in a multi-processing arrangement may also be employed to execute the sequences of instructions contained in main memory. In alternative embodiments of the present invention, hard-wired circuitry may be used in place of or in combination with software instructions. Thus, the various embodiments of the present invention are not limited to any specific combination of hardware circuitry and software.

The controller 70 includes at least one computer readable medium or memory, such as the controller memory, for holding instructions programmed according to the teachings of the present invention and for containing data structures, tables, records, or other data that may be necessary to implement various of the embodiments of the present invention. Examples of computer readable media are compact discs, hard disks, floppy disks, tape, magneto-optical disks, PROMs (EPROM, EEPROM, flash EPROM), DRAM, SRAM, SDRAM, or any other magnetic medium, compact discs (e.g., CD-ROM), or any other optical medium, punch cards, paper tape, or other physical medium with patterns of holes, a carrier wave (described below), or any other medium from which a computer can read.

Stored on any one or on a combination of computer readable media, the present invention includes software for controlling the controller 70 for driving a device or devices for implementing the invention and/or for enabling the controller to interact with a human user. Such software may include, but is not limited to, device drivers, operating systems, development tools, and applications software. Such computer readable media further includes the computer program product of the present invention for performing all or a portion (if processing is distributed) of the processing performed in implementing the invention.

The computer code devices of the present invention may be any interpretable or executable code mechanism, including but not limited to scripts, interpretable programs, dynamic link libraries (DLLs), Java classes, and complete executable programs. Moreover, parts of the processing of the present invention may be distributed for better performance, reliability, and/or cost.

The term “computer readable medium” as used herein refers to any medium that participates in providing instructions to the processor of the controller 70 for execution. A computer readable medium may take many forms, including but not limited to, non-volatile media, volatile media, and transmission media. Non-volatile media includes, for example, optical, magnetic disks, and magneto-optical disks, such as the hard disk or the removable media drive. Volatile media includes dynamic memory, such as for example the main memory. Moreover, various forms of computer readable media may be involved in carrying out one or more sequences of one or more instructions to processor of controller for execution. For example, the instructions may initially be carried on a magnetic disk of a remote computer. The remote computer can load the instructions for implementing all or a portion of the present invention remotely into a dynamic memory and send the instructions over a network to the controller 70.

The controller 70 may be locally located relative to the deposition system 1, or may be remotely located relative to the deposition system 1. For example, the controller 70 may exchange data with the deposition system 1 using at least one of a direct connection, an intranet, the Internet and a wireless connection. The controller 70 may be coupled to an intranet at, for example, a customer site (i.e., a device maker, etc.), or the controller 70 may be coupled to an intranet at, for example, a vendor site (i.e., an equipment manufacturer). Additionally, for example, the controller 70 may be coupled to the Internet. Furthermore, another computer (i.e., controller, server, etc.) may access, for example, the controller 70 to exchange data via at least one of a direct connection, an intranet, and the Internet. As also would be appreciated by those skilled in the art, the controller 70 may exchange data with the deposition system 1 via a wireless connection.

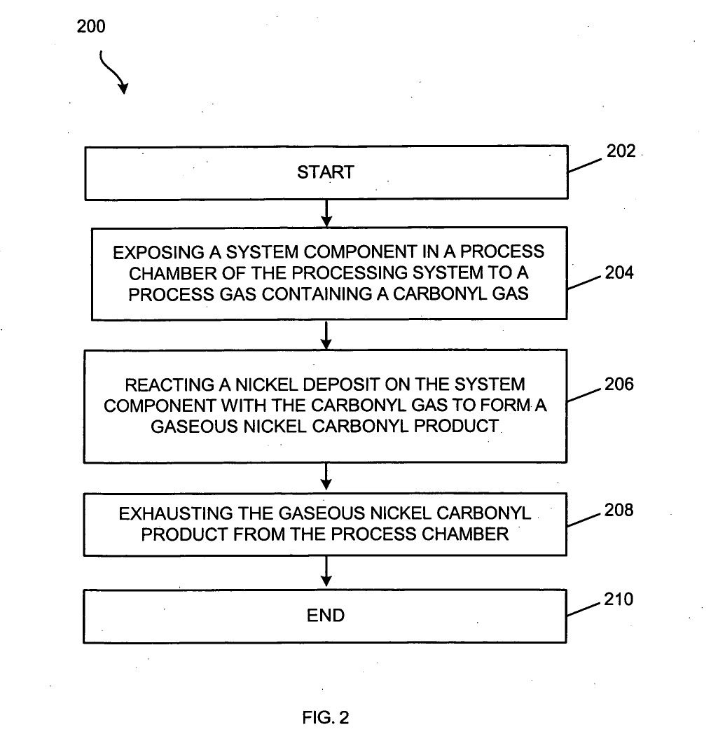

FIG. 2 is a process flowchart for dry cleaning nickel deposits from a processing system according to an embodiment of the present invention. The processing system may be the processing system 1 depicted in FIG. 1 including multiple system components exposed to a process environment during processing of a substrate. The process 200 starts in step 202. In step 204, a system component in a process chamber of the processing system is exposed to a process gas containing a carbonyl gas (e.g., a thermal or plasma or ultraviolet excited carbonyl gas). The carbonyl gas can include carbon dioxide (CO₂), carbon monoxide (CO), or a combination thereof. In addition to the carbonyl gas, the process gas may include an inert gas. The inert gas can include nitrogen gas (N₂), a noble gas (e.g., He, Ar), or a combination thereof.

According to an embodiment of the present invention, the system component may be maintained at a temperature between about 20° C. and about 600° C. during the dry cleaning process 200. Variations in the system component temperatures during the dry cleaning can be ±5° C. Different system components may be maintained at different temperatures. For example, a process chamber wall may be maintained at a temperature between about 50° C. and about 100° C. and the substrate holder may be maintained at a temperature between about 100° C. and about 600° C. In one embodiment of the present invention, the process gas pressure in the process chamber may be maintained between about 1 mTorr and about 1,000 Torr. Variations in the process gas pressure maintained during the dry cleaning can be ±2%. In another embodiment of the present invention, the process gas pressure in the process chamber may be maintained between about 10 Torr and about 500 Torr.

In step 206, a nickel deposit on the system component is reacted with the carbonyl gas in a dry cleaning process to form a gaseous nickel carbonyl product. For example, the volatile nickel carbonyl product may include Ni(CO)₄ or derivatives thereof.

As previously noted, the process gas may include CO and N₂ or Ar, and may include CO₂ and N₂ or Ar. Dissociation of CO₂ into CO is followed by reaction of CO with the nickel deposit on system components. Embodiments using CO instead of CO₂ may follow direct reaction with the nickel deposits without the CO₂ dissociation step.

In step 208, the gaseous nickel carbonyl product is exhausted from the process chamber.

According to one embodiment of the present invention, the dry cleaning process 200 may be performed in a continuous gas flow mode in which a flow of the process gas is continuous, where the process gas is continuously flowed through the processing system while a desired process gas pressure, for example between about 1 mTorr and about 1,000 Torr, is maintained in the process chamber. Variations in the process gas pressure maintained during the dry cleaning in the continuous gas flow mode can be ±2% of the targeted pressures. The desired process gas pressure may be maintained in the process chamber by controlling the flow rate of the process gas to the process chamber and controlling the exhaust rate of the process gas from the process chamber. In one example, a substantially constant process gas pressure may be maintained in the process chamber during the exposure step 204. In another embodiment of the present invention, the process gas pressure may be varied during the step 204.

According to another embodiment of the present invention, the dry cleaning process 200 may be performed in a static gas mode in which a flow of the process gas is terminated, where the process chamber is pressurized with the process gas, and little or no gas is exhausted from the process chamber during the exposure step. For example, a static pressure set anywhere between about 1 mTorr and about 1,000 Torr, can be used in the static gas mode of the present invention. Variations in the process gas pressure maintained during the dry cleaning in the static gas mode can be ±10% of the targeted pressures. When using the static gas mode, the steps of the process 200 may be carried out more than once until desired removal of the nickel deposits from the system components has been achieved.

The process 200 may be carried out for a predetermined time period known to result in adequate removal of the nickel deposits. Alternately, the status of the dry cleaning process 200 may be monitored to ensure adequate removal of the nickel deposits from the system components.

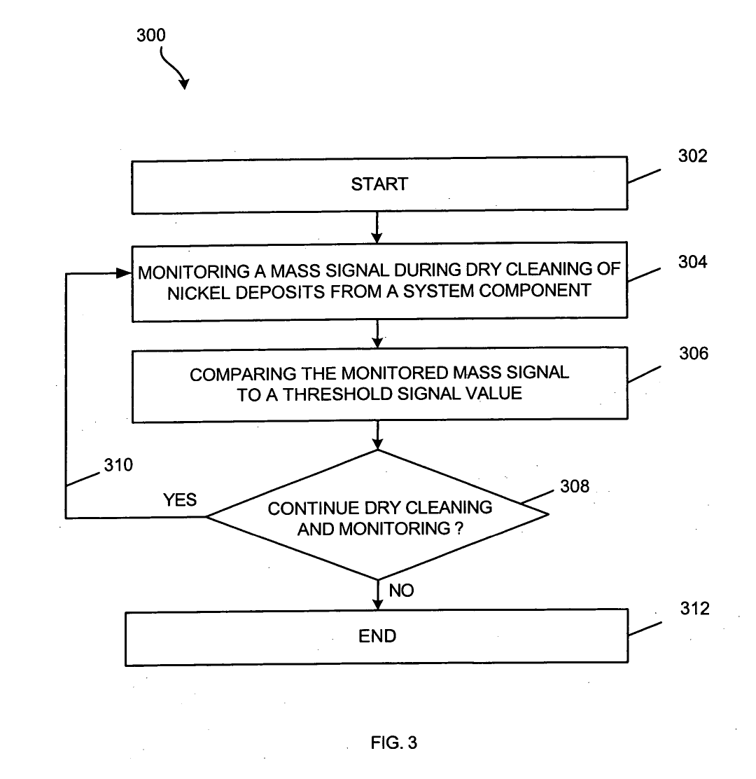

FIG. 3 is a process flowchart for monitoring and controlling dry cleaning of nickel deposits from a processing system according to an embodiment of the present invention. The process 300 starts in step 302. In step 304, a mass signal is monitored using a mass sensor during the dry cleaning of nickel deposits from a system component. Referring back to FIG. 1, a mass signal corresponding to a gaseous nickel carbonyl product or a carbonyl cleaning gas in the process chamber 10 may be measured by the mass sensor 54. Alternately, a mass signal corresponding to a gaseous nickel carbonyl product or a carbonyl cleaning gas in the exhausted gas from the process chamber 10 may be measured by the mass sensor 56. The mass signal may correspond to the gaseous nickel carbonyl product or fragments thereof. In one example, the gaseous nickel carbonyl product monitored may be Ni(CO)₄ with a molecular weight of 170 atomic mass units. In addition, or in the alternative, the mass signal may correspond to a carbonyl cleaning gas or fragments thereof.

In step 306, the monitored mass signal is compared to a threshold signal value. The threshold signal value may, for example, be determined based on prior removal processes that are known to indicate desired removal of nickel deposits from the processing system.

In step 308 a decision is made, based on the comparison step 306, whether to continue the dry cleaning and monitoring step 304 as shown by process flow 310 or to end the process 300 in step 312.

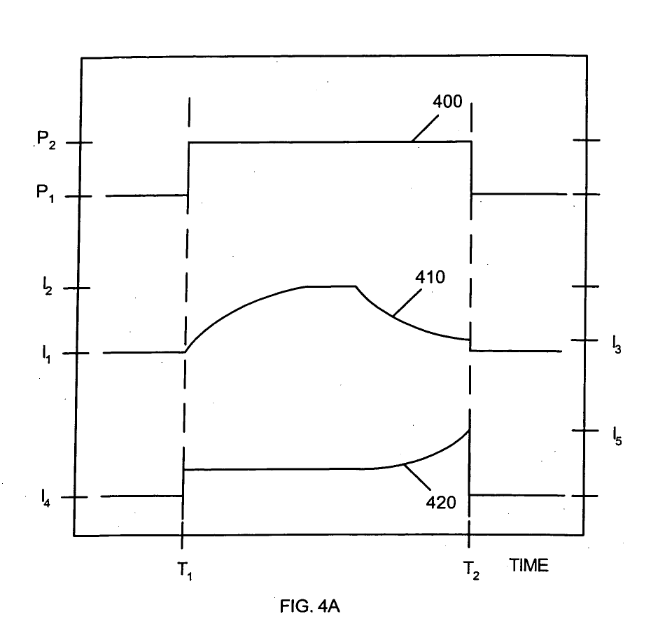

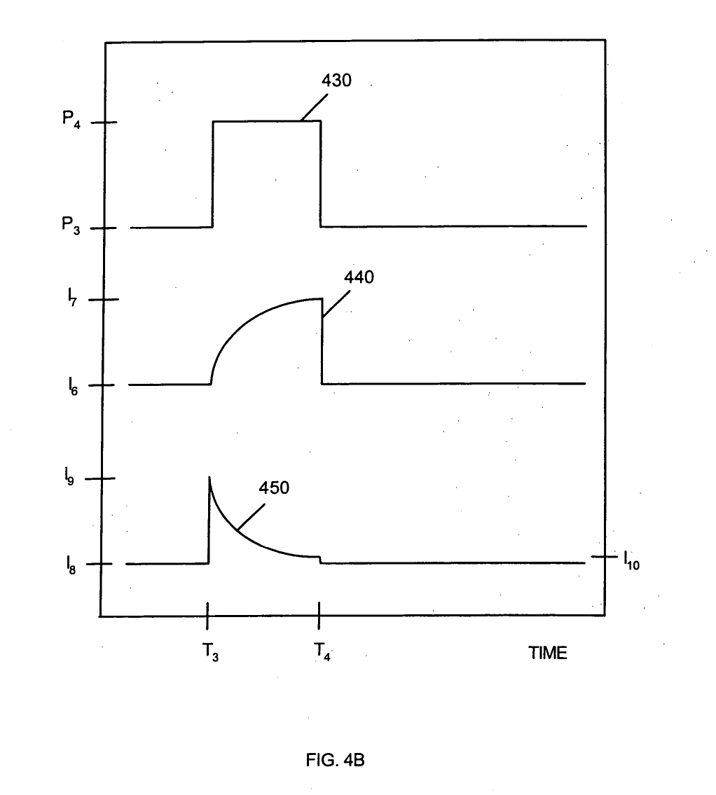

FIG. 4A shows monitoring of dry cleaning nickel deposits from a processing system according to an embodiment of the present invention. FIG. 4A shows a continuous gas flow mode where, at time T₁, a carbonyl cleaning gas is flowed into the process chamber and the process gas pressure in the process chamber, is increased from P₁ to P₂ as seen in process gas pressure curve 400. For example, the mass signal in curve 410 can correspond to a gaseous nickel carbonyl product in the process chamber or in the process chamber exhaust. At time T₁, the intensity of the mass signal in curve 410 increases from a base signal value I₁ to a signal value I₂, and subsequently decreases to a threshold signal value I₃ at time T₂. In another example, the mass signal in curve 420 can correspond to the carbonyl cleaning gas in the process chamber or in the process chamber exhaust. At time T₁, the mass signal in curve 420 increases from a base signal value I₄ to a threshold signal value I₅ at time T₂.

The decision in step 308 of FIG. 3 may be based on whether the mass signal value in curve 410 in FIG. 4A has reached the threshold signal value I₃ during the continuous gas flow mode, thereby indicating that the amount of gaseous nickel carbonyl products in the process chamber has reached an acceptable low level. In addition, or in the alternative, the decision in step 308 of FIG. 3 may be based on whether the mass signal value in curve 420 has reached the threshold signal value I₅. In FIG. 4A, the dry cleaning process is stopped at time T₂.

FIG. 4B shows monitoring of dry cleaning nickel deposits from a processing system according to another embodiment of the present invention. FIG. 4B, shows a static gas mode where, at time T₃, a carbonyl cleaning gas is flowed into the process chamber and the process gas pressure in the process chamber is increased from P₃ to P₄ as seen process gas pressure curve 430. In one example, the mass signal in curve 440 can correspond to a gaseous nickel carbonyl product in the process chamber. At time T₃, the intensity of the mass signal in curve 440 increases from a base signal value I₆ to a threshold value I₇ at time T₄. For example, the mass signal in curve 450 can correspond to the carbonyl cleaning gas in the process chamber or in the process chamber exhaust. At time T₃, the intensity of the mass signal in curve 450 increases from a base value I₈ to a signal value I₉, but subsequently decreases to a threshold value I₁₀ at time T₄.

The decision in step 308 of FIG. 3 may be based on whether the mass signal value curve 440 in FIG. 4B has reached the threshold signal value I₇ during the static gas mode, thereby indicating that all or substantially all the nickel deposits have been volatilized from the system components. In addition, or in the alternative, the decision in step 308 of FIG. 3 may be based on whether the mass signal value in curve 450 has reached the threshold signal value I₁₀. In FIG. 4B, the dry cleaning process is stopped at time T₄.

According to an embodiment of the present invention, the controller 70 depicted in FIG. 1 may be programmed such that the processing system 1 can perform the process and monitoring steps shown in FIGS. 2-4. For example, the controller 70 can be programmed to control the gas delivery system 40 during the process 200, including controlling the flow rate and composition of the process gas into the process chamber 10, and can be programmed to maintain the desired process gas pressure in the process chamber 10 by controlling the valve 36. In addition, the controller 70 can be programmed to perform the monitoring process 300, including monitoring selected mass signals, comparing the monitored mass signals to threshold values, and deciding whether to continue the monitoring or to end the process.

Numerous modifications and variations on the present invention are possible in light of the above teachings. It is, therefore, to be understood that within the scope of the accompanying claims, the invention may be practiced otherwise than as specifically described herein.

1. A method for dry cleaning a processing system, comprising:
exposing a system component in a process chamber of the processing system to a process gas comprising a carbonyl gas;
reacting a nickel deposit on the system component with the carbonyl gas to form a gaseous nickel carbonyl product; and
exhausting the gaseous nickel carbonyl product from the process chamber.

2. The method according to claim 1, wherein the exposing a system component comprises:
exposing the system component to at least one of thermal or plasma or ultraviolet excited carbonyl gas.

3. The method according to claim 1, wherein the reacting a nickel deposit comprises:
heating at least one of nickel metal, nickel silicide, nickel oxide, or a combination thereof of the nickel deposit with the carbonyl gas.

4. The method according to claim 1, wherein the exposing a system component comprises:
exposing at least one of a chamber wall, a substrate holder, an electrode, a shield, a ring, a baffle, or a liner to the carbonyl gas.

5. The method according to claim 1, wherein the exposing a system component comprises:
exposing the system component to at least one of CO₂, CO, or a combination thereof.

6. The method according to claim 5, wherein the exposing a system component further comprises:
exposing the system component to an inert gas.

7. The method according to claim 1, further comprising:
maintaining the system component at a temperature between about 20° C. and about 600° C. during the exposing.

8. The method according to claim 1, further comprising:
maintaining the system component at a temperature between about 50° C. and about 100° C. during the exposing.

9. The method according to claim 1, further comprising:
maintaining a process gas pressure between about 1 mTorr and about 1000 Torr in the process chamber during the exposing.

10. The method according to claim 1, further comprising:
maintaining a process gas pressure between about 10 Torr and about 500 Torr in the process chamber during the exposing.

11. The method according to claim 1, wherein the exposing a system component comprises:
exposing in a static gas mode in which a flow of the process gas is terminated.

12. The method according to claim 1, wherein the exposing a system component comprises:
exposing in a continuous gas flow mode in which a flow of the process gas is continuous.

13. The method according to claim 1, wherein the reacting a nickel deposit comprises:
forming Ni(CO)₄ as the gaseous nickel carbonyl product.

14. The method according to claim 1, further comprising:
monitoring a mass signal from the carbonyl gas or the gaseous nickel carbonyl product;
comparing the mass signal to a threshold signal value; and
terminating the exposing upon the mass signal reaching the threshold signal value.

15. The method according to claim 14, wherein the exposing a system component comprises:
exposing in a static gas mode in which a gas flow of the process gas is terminated.

16. The method according to claim 14, wherein the exposing a system component comprises:
exposing in a continuous gas flow mode in which a gas flow of the process gas is continuous.

17. A method for dry cleaning a processing system, comprising:
exposing a system component in a process chamber to a process gas comprising thermal or plasma or ultraviolet excited CO, CO₂, or a combination thereof;
reacting a nickel deposit comprising at least one nickel metal, nickel silicide, or nickel oxide on the system component with the carbonyl gas in a dry cleaning process to form gaseous Ni(CO)₄; and
exhausting the gaseous Ni(CO)₄ from the process chamber.

18. The method according to claim 17, wherein the exposing a system component comprises exposing in a continuous gas flow exposure in which a flow of the process gas is continuous, and the method further comprises:
monitoring a mass signal from the CO, CO₂, or gaseous Ni(CO)₄ during the exposing;
comparing the mass signal to a threshold signal value; and
terminating the exposing upon the mass signal reaching the threshold signal value.

19. The method according to claim 18, wherein the exposing a system component comprises exposing in a static gas exposure in which a flow of the process gas is terminated, and the method further comprises:
monitoring a mass signal from the CO, CO₂, or gaseous Ni(CO)₄ during the exposing;
comparing the mass signal to a threshold signal value; and
terminating the exposing upon the mass signal reaching the threshold signal value.

20. A computer readable medium containing program instructions for execution on a processor, which when executed by the processor, cause a processing system to perform a dry cleaning process comprising the steps of:
introducing a process gas comprising a thermal or plasma or ultraviolet excited carbonyl gas to a process chamber of the processing system;
adjusting at least one of a temperature and a pressure in the process chamber to produce a gaseous nickel carbonyl product by reacting a nickel deposit on a system component within the process chamber to the carbonyl gas; and
exhausting the gaseous nickel carbonyl product from the process chamber.

21. The computer readable medium according to claim 20, which when executed causes the processing system to perform the further step of:
monitoring a mass signal from the nickel carbonyl product to control the dry cleaning process.

22. A system for dry cleaning a processing system, comprising:
means for exposing a system component in a process chamber to a process gas comprising a carbonyl gas;
means for reacting a nickel deposit on the system component with the carbonyl gas to form a gaseous nickel carbonyl product; and
means for exhausting the gaseous nickel carbonyl product from the process chamber.

23. The system according to claim 22, further comprising:
means for generating an excited carbonyl gas.

24. The system according to claim 23, wherein the means for generating an excited carbonyl gas comprises:
a thermal or plasma or ultraviolet source for excitation of the carbonyl gas.

25. The system according to claim 22, wherein the means for reacting a nickel deposit comprises:
means for heating the system component to a temperature between about 20° C. and about 600° C.

26. The system according to claim 22, wherein the means for reacting a nickel deposit comprises:
means for maintaining a process gas pressure in a static mode in which a gas flow of the process gas is terminated.

27. The system according to claim 22, wherein the means for reacting a nickel deposit comprises:
means for maintaining a process gas pressure in a continuous mode in which a gas flow of the process gas is continuous.

28. The system according to claim 22, further comprising:
means for measuring the gaseous nickel carbonyl product.

29. The system according to claim 28, wherein the means for measuring the gaseous nickel carbonyl product comprises a mass sensor.
